(19) United States
(12) Patent Application Publication
(10) Pub. No.: US 2023/0231068 A1
(43) Pub. Date: Jul. 20, 2023

(54) PHOTOVOLTAIC POWER GENERATION APPARATUS

(71) Applicant: SOLAR EARTH TECHNOLOGIES LTD., VANCOUVER (CA)

(72) Inventors: Meng Wang, Vancouver (CA); Junbiao Zhang, Mountain View, CA (US); Xinghua Wang, Vancouver (CA)

(21) Appl. No.: 18/190,762

(22) Filed: Mar. 27, 2023

Related U.S. Application Data
(63) Continuation-in-part of application No. 16/097,043, filed on Oct. 26, 2018, now abandoned.
(60) Provisional application No. 62/329,461, filed on Apr. 29, 2016.

(51) Int. Cl. H01L 31/054; H01L 31/043

(52) U.S. Cl. CPC H01L 31/0547; H01L 31/043

(57) ABSTRACT

The present invention relates to three dimensional photovoltaic structures and a power generation apparatus comprising same. The photovoltaic structure comprises a light transmitting solid optical core having a longitudinal axis, a top end, a bottom end and one or more side walls, wherein the top end has an exposed outer surface to receive light. A photovoltaic layer surrounds at least a portion of one or more of the side walls of the optical core and an optical cladding layer surrounds the photovoltaic layer.

### CROSS REFERENCE TO RELATED APPLICATIONS

This application is a continuation-in-part of U.S. Application No. 16/097,043, filed Oct. 26, 2018, which is a National Stage Application of International Application No. PCT/CA2017/050523, filed Apr. 28, 2017, which claims priority to and the benefit of U.S. Provisional Application No. 62/329,461, filed Apr. 29, 2016. The disclosures of which are incorporated herein by reference in their entirety.

### FIELD OF THE INVENTION

The present invention pertains to the field of photovoltaic power generation and in particular to three dimensional photovoltaic power generation apparatus, such as solar cells.

### BACKGROUND

Most photovoltaic solar cells are flat designs where sunshine harvest takes place on a 2-D semiconductor layout. This is due to the fact that most of photons carried in solar radiation can only penetrate into the solid state semiconductor by a few microns (the probability for a photon to reach deeper areas inside a solar cell decreases exponentially with the depth), and so photovoltaic interaction between photons from the solar radiation and electrons in semiconductors mainly takes place on the surface of the solar cells. Due to advances in nanotechnology, semiconductor materials can be manipulated at molecular and atomic levels, and it has been possible stack a few (two or three) PN junction layers on a solar cell to produce so-called tandem solar cells with higher photovoltaic conversion rate by harvesting more solar radiation energies in broader spectrums. Nevertheless, further stacking of such layers is limited by the fact that photons simply cannot reach even deeper layers of solid-state materials.

As a consequence, the photovoltaic conversion rate is limited by the Event Cross Section (ECS), defined by the surface area of a given photovoltaic solar cell where the photovoltaic interaction (the ‘event’) takes place. As typical state of art a conversion rate of about 10-20% have been achieved, which means only 10-20% of energy carried out by the solar radiation that reaches this area is converted into the electric power.

Efforts have been made to provide photovoltaic structures/devices/cells with improved conversion rate. US 20120279561 discloses a hollow photovoltaic fiber, which includes semiconductor formed on the inner surface of a hollow tube or on a flexible substrate subsequently formed into a hollow tube. The hollow photovoltaic fiber can be suitable for a variety of semiconductor devices, including solar cells. This references discloses that light entering the hollow photovoltaic fiber deposits energy in the semiconductor as it travel through the tube. The hollow tubes allow the incident light coming from all directions and a big portion of photons that cannot participate in a photovoltaic event and not to be absorbed by the tube would escape from tube and have no chance to contribute again.

US 2013/0104979 discloses a solar device, which includes a light condenser, a light guide member, a number of optical fibers and a converter end. The light condenser is configured for condensing incident light. The light guide member converts the condensed light into a plurality of focused light beams. The optical fibers receive the condensed light beams. The converter end includes a photoelectric converter configured for receiving and converting light from the optical fibers into electricity.

US 2013/0186452 discloses a photovoltaic structure, which includes an array of photovoltaic nanostructures, and a photovoltaic device, the photovoltaic device being at least semi-transparent. The array is positioned relative to the photovoltaic device such that light passing through the photovoltaic device strikes the array. The nanostructure disclosed in this reference includes an array of nanocables extending from a substrate. The nanocables have a spacing and surface texture defined by inner surfaces of voids of a template; an electrically insulating layer extending along the substrate; and at least one layer overlaying the nanocables.

US 2015/0263302 discloses photovoltaic device comprising patterned nanofibers. The nanofiber comprises a core, which extends along the axis of the nanofiber, and its main component includes Ag(NH₃)₂ + or AgNO₃; a shell, which extends along the nanofiber and coats the core of the nanofiber, and its main component of the shell structure includes: PVP, TBAP, SDS, grapheme, PMAA or PFBT nanoparticle.

US 2016/0043250 discloses three-dimensional photovoltaic devices comprising non-conductive cores. The photovoltaic structure disclosed in this reference comprises a dielectric material layer comprising a planar portion having a uniform thickness and an array of protruding portions extending from a planar surface of the planar portion; and a layer stack located on the dielectric material layer and comprising a core conductive material layer, a photovoltaic material layer, and a transparent conductive material layer. The core conductive material layer is in contact with the planar surface and the protruding portions of the dielectric material layer, the transparent conductive material layer is spaced from the core conductive material layer by the photovoltaic material layer and each combination of a protruding portion of the dielectric material layer and portions of the layer stack surrounding the protruding portion constitutes a photovoltaic bristle. The basic building blocks in the device of this reference are the photovoltaic bristles, which also allow incident lights coming from all directions and also allow escape of a large portion of light without being able to participate in photovoltaic event.

There is still a need for photovoltaic power generator structures/solar cells which can exhibit an improved conversion rate from solar radiations to electric power.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide three dimensional photovoltaic structures and a power generation apparatus comprising same.

In accordance with an aspect of the present invention, there is provided a photovoltaic structure, comprising: a light transmitting solid optical core having a longitudinal axis, having a top end, a bottom end and one or more side walls. The top end having an exposed outer surface to receive light. A photovoltaic layer surrounding at least a portion of one or more of the side walls of the optical core, and an optical cladding layer surrounding the photovoltaic layer.

In various embodiments, the photovoltaic layer and the cladding layer surround the bottom end of the optical core. In various embodiments, such a structure has a shape like a geometric prism.

In various embodiments, the bottom end is a point; or wherein the bottom end includes a surface of nonzero area. In various embodiments, such a structure has a conical shape.

In various embodiments, the optical cladding layer has a refractive index greater than a refractive index of the photovoltaic layer and the optical core. In various embodiments, the optical core has a refractive index which is approximately equal to a refractive index of the photovoltaic layer.

In various embodiments, the optical core is made of non-conductive, non-opaque and/or an optically permeable material.

In various embodiments, the photovoltaic structure further comprises an additional layer at or near the top end, the additional layer having an anti-reflective light transmitting outer surface and a highly reflective inner surface.

In various embodiments, the photovoltaic layer comprises a multi-layered structure comprising: an interior metallic layer in contact with the optical core, one or more semiconductor layers comprising one or more PN junctions and surrounding the interior layer, and an exterior metallic layer surrounding the semiconductor layer, wherein the interior metallic layer and the exterior metallic layer are electrically coupled to conductors for providing an electric voltage. In various embodiments, the interior and exterior metallic layers have high optical permeability and electric conductivity.

In various embodiments, the first and second metallic layers cover the entire length of the structure. In various embodiments, the first and second metallic layers cover the length of the structure from the bottom end up to the additional layer.

In various embodiments, the photovoltaic structure comprises a plurality of the multi-layered structures.

In various embodiments, the photovoltaic layer comprises multiple tandem semiconductor layers with spectrum selectivity in axial, radial and/or circular direction.

In various embodiments, the semiconductor layer has a polarity to impart movement of electrons toward or away from the optical core during a photovoltaic event.

In various embodiments, the cross sectional shape of the optical core, the photovoltaic layer and the cladding layer are same.

In accordance with another aspect, there is provided a three dimensional photovoltaic structure, which comprises a light transmitting solid optical core having a longitudinal axis, the core having a top end, a bottom end and one or more side walls; the top end having an exposed outer surface to receive light; a photovoltaic layer adjacent the optical core and surrounding the bottom end of the optical core and the one or more of the side walls of said optical core; and an optical cladding layer adjacent the optical core and surrounding said photovoltaic layer; wherein said photovoltaic layer surrounding the bottom end of the optical core and the one or more side walls of said optical core, and the optical cladding layer surrounding said photovoltaic layer, together define a substantially closed light sealing optical chamber, wherein the three dimensional structure receives light substantially through the exposed outer surface of the top end of the optical core, the photovoltaic layer receives light from the core, and the optical cladding layer receives light through the photovoltaic layer, and reflect it back towards the photovoltaic layer.

In accordance with another aspect of the present invention, there is provided a three-dimensional photovoltaic power generation apparatus, comprising: a base structure having an upper surface and a lower surface; wherein the bottom end of each of the plurality of photovoltaic structures is in direct or indirect association/contact with the upper surface of the base structure.

In various embodiments, the apparatus further comprises one or more side walls to encase the plurality of the photovoltaic structures.

In various embodiments, the apparatus further comprises a stuffing layer between adjacent photovoltaic structures.

In various embodiments, the apparatus further comprises a stuffing layer between the bottom end of the photovoltaic structures and the upper surface of the base structure to provide the indirect association/contact.

In various embodiments, in the apparatus comprising the photovoltaic structures having conical shape, the bottom end of each of the conical shaped photovoltaic structures are in contact with the upper surface of the base structure to provide the direct association.

In various embodiments, in the apparatus comprising the photovoltaic structures shaped as geometric prism, the upper surface of the base structure has a plurality of receiving structures shaped to accommodate the bottom end of corresponding photovoltaic structures.

In various embodiments, the photovoltaic layer and the cladding layer surround the bottom end of the optical core.

In various embodiments, the photovoltaic layer and the cladding layer surrounding the bottom end of the optical core is integral to the base structure.

In various embodiments, the upper surface of the base structure comprises a layered structure comprising a photovoltaic layer and the cladding layer, wherein each layer abuts with the corresponding layer of the photovoltaic structures.

In various embodiments, photovoltaic structures have the same length. In various embodiments, the photovoltaic structures have different lengths.

Embodiments of the present invention provide improved photovoltaic structures to systematically increase the ECS for a given solar cell with given surface area, without altering the physical and chemical properties of the semiconductor. The photovoltaic structures of the present invention provide increased area of ECS so that the photons carried in solar radiation have more opportunities to meet and interact with the electrons in the material. The optical core of the present invention provides an ideal chamber to seal the incident light inside the photovoltaic structure and increases the likelihood of photons interacting with the electrons of the photovoltaic layer. The presence of optical cladding layer further assists in increasing the ECS.

### BRIEF DESCRIPTION OF THE DRAWINGS

FIG. 1A illustrates a top view of a layered photovoltaic structure in accordance with an embodiment of the present invention;

FIG. 1B illustrates a top view of a layered photovoltaic structure in accordance with an embodiment of the present invention;

FIG. 2A illustrates a perspective view of an optical core in accordance with an embodiment of the present invention;

FIG. 2B illustrates a perspective view of an optical core in accordance with an embodiment of the present invention;

FIG. 3 illustrates a sectional view of a layered photovoltaic structures in accordance with an embodiment of the present invention;

FIG. 4A illustrates a sectional view of the photovoltaic structures comprising core and a single semiconductor layer;

FIG. 4B illustrates a sectional view of the photovoltaic structures comprising core and multiple spectrum-selective semiconductor layers;

FIG. 4C illustrates a sectional view of the photovoltaic structures comprising core and multiple tandem semiconductor layers with spectrum selectivity in axial and radial direction;

FIG. 5 illustrates a top view of the photovoltaic structure depicting spectrum selectivity along the circular direction in accordance with an embodiment of the present invention;

FIGS. 6A-6C illustrate different configurations of metallic layers on the optical core in accordance with certain embodiments of the present invention;

FIG. 6D is the top view of the embodiment of FIG. 6A;

FIGS. 7A-7F illustrate top views of layered photovoltaic structures comprising stuffing layers of different shapes, in accordance with certain embodiments from the present invention;

FIG. 8A illustrates a perspective view of the photovoltaic power generation apparatus in accordance with one embodiment of the present invention;

FIG. 8B illustrates a perspective view of the photovoltaic power generation apparatus in accordance with one embodiment of the present invention;

FIG. 8C illustrates a perspective view of the photovoltaic power generation apparatus in accordance with one embodiment of the present invention;

FIGS. 9A and 9B illustrate top views of photovoltaic structures packed and encased in a base structure in accordance with certain embodiments of the present invention;

FIGS. 10A-10C illustrate top views of base structures showing shapes of photovoltaic structures in accordance with certain embodiments of the present invention;

FIGS. 11A-11H illustrate packing configurations, relative heights and cross sectional shapes of photovoltaic structures in accordance with embodiments of the present invention;

FIG. 12 illustrates the unit structure of base structure and its integration with a corresponding photovoltaic structure in accordance with an embodiment of the present invention;

FIG. 13A illustrates a photovoltaic power generation apparatus with additional stuffing layer between adjacent photovoltaic structures, in accordance with an embodiment of the present invention;

FIG. 13B illustrates a photovoltaic power generation apparatus without additional stuffing between adjacent photovoltaic structures, in accordance with an embodiment of the present invention;

FIG. 14 illustrates a photovoltaic power generation apparatus with stuffing layer between cone shaped photovoltaic structures;

FIGS. 15A-15C illustrate electric connections inside a photovoltaic power generation apparatus, in accordance with an embodiment of the present invention;

FIG. 16 illustrates variations in geometric shapes of the top end of the photovoltaic structures, in accordance with certain embodiments of the present invention; and

FIG. 17 illustrates an array of photovoltaic power generation apparatus disposed on a surface.

### DETAILED DESCRIPTION OF THE INVENTION

As used herein, the term “about” refers to a +/-10% variation from the nominal value. It is to be understood that such a variation is always included in a given value provided herein, whether or not it is specifically referred to.

As used herein, the term “geometric prism” refers to a three-dimensional shaped structure, for example a microstructure, having top and bottom faces connected by flat or curved sidewalls. This type of shape is also referred to herein as a microprism, and includes cylinders, cubes, cuboids, rectangular prisms, hexagonal prisms, and the like. In various embodiments, the top and bottom faces are parallel and are similarly sized and shaped. However, it is also envisioned that the structure may have differently sized and/or shaped top and bottom faces, for example in accordance with a frustro-conical shape.

As used herein, the term “conical shape” refers to a three dimensional shaped structure having a top face and non-parallel sidewalls tapering to a point, or tapering to a bottom face having a small but possibly nonzero area. The absence or reduction in size of the bottom face mitigates the need for a photovoltaic structure at this location. The conical shaped structures can have a cross section shape of circle, triangular, square, pentagon, hexagon, etc. Conical shaped structures may be cones, pyramids, or the like.

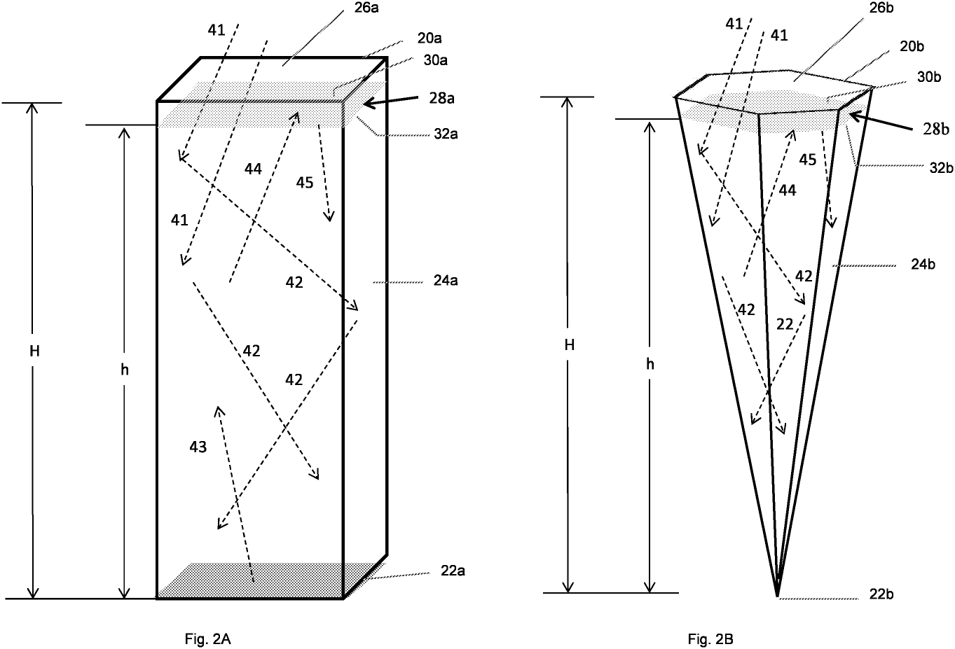

As used herein, the term “three dimensional photovoltaic structure” refers to a macroscopic structure as depicted in FIGS. 2A-B, 3 and 8A-C. Such a structure has a height about 0.3 cm to about 20 cm, preferably 0.5 to 10 cm, with an aspect ratio between the length and width no more that 1:0.5 (width:height) and no less than 1:20, preferably between 1:1 and 1:6. The three-dimensional photovoltaic structure referred herein provides an “operationally closed light capturing optical chamber”, having a top, a bottom and sides for providing multiple contact/reflection points within the structure, such that the incident light received from various angles at the top surface into the three-dimensional photovoltaic structure can be reflected randomly within the “operationally closed structure.” Such a configuration cannot be achieved with photovoltaic bristles such as fiber optics. This is because, for example, fiber optics can only receive light in a narrow range due to their small cross section. The three-dimensional structure can be tuned to reflect light in solar spectrum, 0.3-3 um of wavelength. The structure may be such that the sidewalls, as well as the top of and bottom, of the structure are separated by a significantly large number of wavelengths of light in this wavelength range. As such, the physical characteristics and behaviour are significantly different when compared to much smaller structures, where structure sidewalls might be separated by a distance on the order of one wavelength.

Unless defined otherwise, all technical and scientific terms used herein have the same meaning as commonly understood by one of ordinary skill in the art to which this invention belongs.

The present invention provides three dimensional photovoltaic structures and a power generation apparatus comprising same.

In one aspect of the present invention, there is provided a three dimensional photovoltaic structure, one or more of which can be used in a power generation apparatus.

The photovoltaic structure of the present invention has a longitudinal axis, a top end and a bottom end, and comprises a light transmitting solid optical core having a top end, a bottom end and side wall(s). The photovoltaic structure further comprises a photovoltaic layer which surrounds the walls of the core, an optical cladding layer which surrounds the photovoltaic layer, and optionally an outermost stuffing layer. The top end of the optical core has an exposed outer surface to receive light.

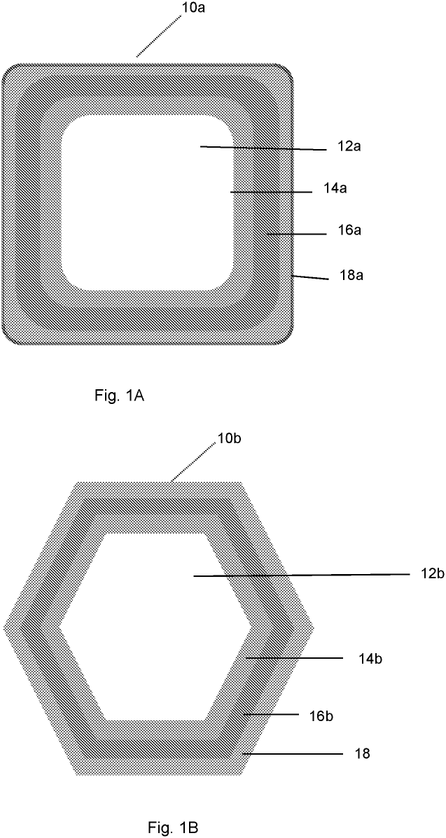

Layered FIG. 1A illustrates a top view of an exemplary layered photovoltaic structure 10a of the present invention showing the core 12a, photovoltaic layer 14a, optical cladding layer 16a, and a stuffing layer 18a. FIG. 1B illustrates a top view of another example of the layered photovoltaic structure 10b of the present invention showing the core 12b, photovoltaic layer 14b, optical cladding layer 16b, and a stuffing layer 18b.

The photovoltaic layer surrounds at least a portion of at least one (i.e. one or more) of the sidewalls. In some embodiments the photovoltaic layer surrounds substantially all of at least one sidewall. In some embodiments the photovoltaic layer surrounds substantially at least part of all of the sidewalls. In some embodiments, the photovoltaic layers surrounds substantially all parts of all of the sidewalls. It should be understood that a photovoltaic layer of larger surface area can in various embodiments result in greater photovoltaic activity. However, at least some photovoltaic activity can still be provided even when the photovoltaic layer does not surround all parts of all sidewalls (i.e. when there are gaps in the photovoltaic layer). Gaps can similarly be provided in the optical cladding layer.

In some embodiments, the sidewalls are substantially flat between their upper end and there lower end. In other embodiments, the sidewalls may be curved between their upper and lower ends. The sidewall upper end refers to the sidewall terminal portion which is proximate to the region of the apparatus which is exposed to light, while the lower and refers to the opposite side will terminal portion.

FIGS. 2A and 2B illustrate perspective view of examples of the optical core in accordance of the present invention, showing a top end 20a, 20b, a bottom end 22a, 22b and side wall(s) 24a, 24b, and an exposed top outer surface 26a, 26b to receive incident light.

The optical core can be made of non-conductive and/or non-opaque materials, known for making the cores of optical fibers. In one embodiment, the optical core is made of a highly optically permeable material. In various embodiments, substantially the entire interior of the solid optical core is com posed of such material.

The refractive index of the optical core and/or photovoltaic layer is higher than the refractive index of the optical cladding layer. In some embodiments, the optical core has a refractive index greater than a refractive index of the photovoltaic layer. In one embodiment, the optical core has a refractive index which is approximately equal to a refractive index of the photovoltaic layer.

The solid optical core in the photovoltaic structures of the present invention conducts incident light with acceptably low or minimal loss of radiation energy, thus making the power generation apparatus/solar cell comprising photovoltaic structures well adaptive to ambient lights and scattered lights, which increases its harvest rate of solar radiation energy in all weather conditions of all seasons.

As depicted in FIGS. 2A and 2B, the incident sunlight may come in a variety of directions from the top surface of the core of the photovoltaic structures. Only the incident lights in a direction parallel with the longitudinal axis of the photovoltaic structures would go through and directly hit the bottom of the structure, and most of incident light in other directions would hit the side walls of the photovoltaic structures before reaching the bottom of the structure.

The photovoltaic structures of the present invention allow a significant portion of the incident lights to be reflected when it penetrates through the photovoltaic layer and hits the optical cladding layer. This reflected light would continue to travel through the photovoltaic structures until they eventually reach the bottom, during which they would meet the walls of the photovoltaic structures a number of times, thereby increasing the opportunities for the photons in the light to meet and interact with the photovoltaic layers.

FIGS. 2A and 2B illustrate paths of incident light inside the core of the photovoltaic structures in accordance with certain embodiments from the present invention. As shown in FIGS. 2A and 2B, the incident light 41 upon entry into the optical core gets reflected back from the wall and/or bottom of the core as rays 42, 43 and 44, thereby increasing the opportunities for the photons in the light to meet and interact with the photovoltaic layers.

In some embodiments, the photovoltaic structure of the present invention further comprises an additional layer at or near the top end, having an anti-reflective light transmitting outer surface and a highly reflective inner surface. The additional layer has limited or minimal impact to the incident light but can significantly reduce the amount of light tending to escape from the photovoltaic structure to the air. In such embodiments, a portion of the photons in the light are reflected back to continue to travel within the photovoltaic structure.

The additional layer with desired light-transmitting outer surface and highly reflective inner surface can be made via methods known in the art, such as thin film deposition method, multilayer coating, nano-structuring, and/or by selecting appropriate material such as gradient index non-opaque material, porous material, Quantum dots are semiconductor nanocrystals, chemical etching, nanopatterning, etc., and is configured such that external light encountering the additional layer is passed through with less than 15% reflection (i.e. reflection of incoming light away from the structure), while more than 50% of the internal light encountering the additional layer is reflected back inward (i.e. reflection to contain light within the structure) over the solar spectrum range 0.3-3 um.

FIGS. 2A and 2B show the additional layer 28a, 28b having light transmitting outer surface 30a, 30b, and reflective inner surface 32a, 32b, wherein the lights rays 44 are reflected back from the inner surface as rays 45 to continue to travel within the photovoltaic structure. In this example, the additional layer 28a, 28b, is provided at a height “h” relative to the height “H” of the optical core.

The photovoltaic structures of the present invention can have one of a variety of shapes such as a cylinder, a geometric prism, a cone, a pyramid, a cube, a cuboid, a rectangle and any combination thereof.

The cone shaped photovoltaic structures can have a variety of cross sectional shapes such as hexagonal, square, rectangular, circular, etc.

In Non-conical photovoltaic structures (such as geometric prisms, cylinders, cubes, etc.), the bottom end of optical core is also surrounded by a photovoltaic layer and an optical cladding layer, so that when the light photons reach the bottom, they get reflected back at the optical cladding layer of the bottom, after a portion of them interact with the photovoltaic layer at the bottom. In such embodiments, reflected light photons would continue to travel from bottom to the top, and may hit the walls a number of times in the journey and continue to interact with the photovoltaic layers on the walls. In such embodiments, the optical cladding layer on the walls and at the bottom of the photovoltaic structures, together with the additional layer, form a substantially closed optical chamber to increase or maximize the likelihood for the incident light to participate in the photovoltaic interactions inside the photovoltaic structures. As a result, the ECS is significantly increased. Furthermore, embodiments wherein the optic core is made of materials with high optical permeability would ensure that the light loss when travelling in this chamber is mitigated or even minimized.

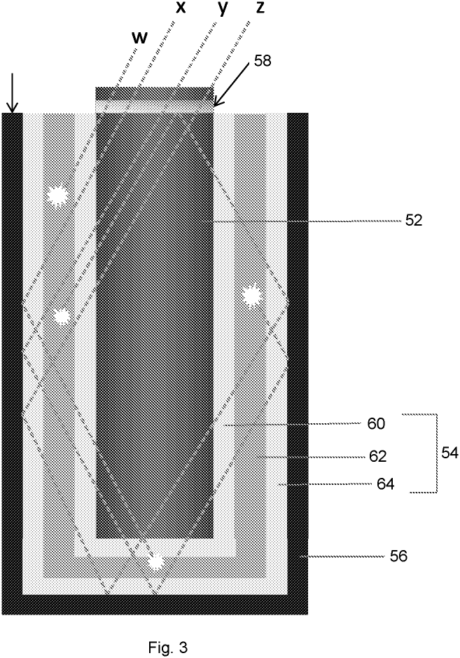

An example of such an embodiment is depicted in FIG. 3, which illustrates a sectional view of a photovoltaic structure showing optical core 52, photovoltaic layer 54 and optical cladding layer 56, both surrounding the walls and bottom of a cylindrical core. The top end of the optical core in this example also has an additional layer 58 having anti-reflective light transmitting outer surface and a highly reflective inner surface.

In case of conical photovoltaic structures the bottom end is defined by the apex or vertex of the cones. In such embodiments, the light-sealing chamber is formed by the walls of the cones and the additional layer at the top. However, in this case the bottom portion of the structure is reduced to a point, or nearly a point, and the sidewalls of the structure are non-parallel, thereby changing the paths of incident and reflected light.

The three dimensional configuration of the photovoltaic structure, having cladding layer exterior to the photovoltaic layer, reflects light back inward into the active three-dimensional region that includes the photovoltaic layer. Therefore, light is repeatedly passed through the photovoltaic layer until it results in a power-generating photovoltaic interaction. This three dimensional configuration, including reflections, leads to more opportunities for the photons carried in the solar radiation to interact with the active photovoltaic layer, which results in a significant increase in the Event Cross Section.

The embodiments of the present invention may employ a range of materials and material thicknesses to achieve the functionality of the invention. For example, materials and thicknesses may be selected so that the layer refractive indices cause a desired amount of internal reflection of light back into the structure interior by the cladding layer. Furthermore, the materials may be selected and configured so that losses of light into the cladding layer are adequately low. For example, the cladding material may be such that between 10-80% of light is reflected back inward at the cladding layer, for wavelengths between 0.3 and 3 um.

The photovoltaic layer is where the photovoltaic conversion takes place. In some embodiments, the photovoltaic layer comprises a multi-layer structure.

In some embodiments, the photovoltaic layer comprises an interior metallic layer in contact with the optical core, one or more conductive layers surrounding the interior metallic layer, and an outer metallic layer surrounding the one or more conductive layers.

FIG. 3 shows an example of the photovoltaic layer 54 comprising an interior metallic layer 60 in contact with the optical core 52, a conductive layer 62 surrounding the interior metallic layer 60, and an outer metallic layer 64 surrounding the conductive layer 62.

In some embodiments, the one or more conductive layers are semiconductor layers, (also referred to as PN junction layers), comprising one or more PN junctions. The PN junctions are configured to generate an electrical voltage in response to photonic bombardment and penetration, in accordance with a photovoltaic effect.

In some embodiments, the photovoltaic layer comprises one semiconductor layer/PN junction layer with its associated interior metallic layer and exterior metallic layer. In some embodiments, the photovoltaic layer comprises a plurality of semiconductor layers /PN junction layers, each with their own respective interior metallic layers and exterior metallic layers.

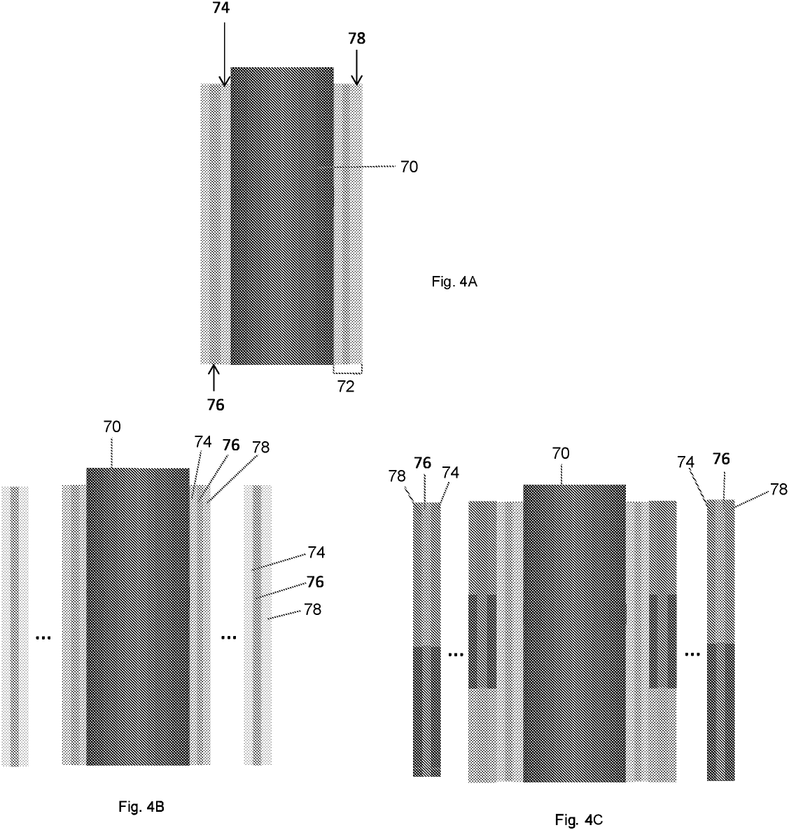

FIG. 4A illustrates a sectional view of an exemplary photovoltaic structure comprising optical core 70 and photovoltaic layer 72 comprising one PN junction 76 between inner metallic layer 74 and outer metallic layer 78. FIGS. 4B and 4C illustrate examples wherein the photovoltaic layer comprises a plurality of semiconductor layers /PN junction layers 76 each with their own respective interior metallic layer 74 and exterior metallic layer 78.

In this disclosure, a semiconductor layer/PN junction layer is referred to as a semiconductor structure formed by two types of semiconductor material, p-type and n-type. Candidate materials and processes for the implementation of the PN junction layers are well known in the art. Suitable material ranges from silicon to non-silicon elements or compounds. In a typical embodiment one may choose thin-film solar cell materials such as amorphous silicon (a-Si), micro-crystalline silicon ((µc-Si), or nano-crystalline silicon (nc-Si). In some embodiments, a PN junction layer may be understood as a P-I-N layer where “I” is meant to be an intrinsic semiconductor layer.

Depending on the polarity of the PN junctions (i.e. the relative locations of the positively and negatively doped semiconductor regions) in the photovoltaic layer in any specific embodiment, the activated electrons may move towards the direction of optical core, or towards the direction of optical cladding layer, when a photovoltaic interaction takes place. In one embodiment, the electrons move toward the direction of the optical core when a photovoltaic event takes place.

In some embodiments, solar radiation spectrum-selectivity is considered when choosing different materials for implementing the photovoltaic layer for the photovoltaic structures of the present invention. While some materials are best tuned to absorb solar energy carried by shorter wavelength photons, some other materials are best tuned to react to longer wavelength photons. The three-dimensional structural nature of the photovoltaic structures provides a possibility of optimizing spatial distribution of semiconductor materials along the circular, axial, and/or radial dimensions.

By applying photovoltaic materials that are best tuned to different wavebands of light to different segments of the photovoltaic structure, one can obtain the spectrum selectivity along the axial direction. An approach in one embodiment is to apply an amorphous silicon coating to the upper part of the photovoltaic structure (microprism or micro-cone) with best spectrum response to green and blue lights wavelengths, and to apply certain µc-Si or nc-Si coating to the lower part of the microprism or micro-cone with best spectrum response to red and infrared wavelengths. Depending on particular considerations a designer can play with this axial spectrum selectivity in a variety of ways in different embodiments.

By overlaying photovoltaic materials that are best tuned to different wavebands of light on successive coating layers surrounding the optical core, one can obtain a photovoltaic structure with spectrum selectivity along the radial direction. An approach in one embodiment is to mimic the tandem PN junctions configuration that has been in industry practice for years, where an amorphous silicon coating is first applied with best spectrum response to green and blue light wavelengths, and then a µc-Si or nc-Si coating is overlaid on top of amorphous silicon coating with best spectrum response to red and infrared wavelengths.

By applying photovoltaic materials that are best tuned to different wavebands of light to different segments of the same photovoltaic coating layer, one can obtain a photovoltaic structure with spectrum selectivity along the circular direction. An approach in one embodiment is to apply an amorphous silicon coating to one half side of the microprism or micro-cone, with best spectrum response to green and blue lights wavelengths, and a µc-Si or nc-Si coating to the other half side of the microprism or micro-cone, with best spectrum response to red and infrared wavelengths.

FIG. 4B illustrates multiple spectrum-selective semiconductor/PN junction layers, and FIG. 4C illustrates multiple tandem semiconductor layers with spectrum selectivity in axial and radial direction. Different shades in these exemplary drawings represent photovoltaic materials best tuned to different wavebands of solar radiation spectrum.

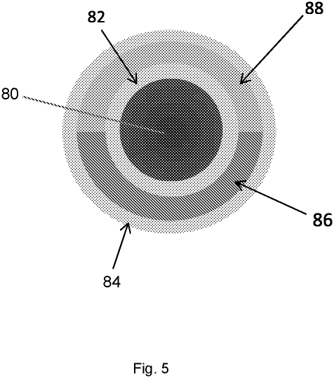

FIGS. 4C and 5 illustrate spectrum selectivity along the three dimensions, wherein FIG. 4C illustrates spectrum selectivity in axial and radial directions, and FIG. 5 illustrates a top view of an example of the photovoltaic structure depicting spectrum selectivity along the circular direction, wherein the optical core 80 is surrounded by interior metallic layer 82. The photovoltaic layer has a photovoltaic coating 86 best tuned to short wavebands, a photovoltaic coating 88 best tuned to long wavebands. The photovoltaic layer is surrounded by the optical cladding layer 84.

The functions of the interior metallic layer and an exterior metallic layer associated with each conductive layer are to capture and collect the electrons (or holes) in the conductive layer that are displaced into the metallic layers as a result of the photovoltaic interaction, and to provide a cathode (anode) electrical connection for the photovoltaic structure, for example to electrically connect with other photovoltaic structures of the same cell. The terms “interior” and “exterior” are meant in respect to the optical core: when the light travels from the optical core to the optical cladding layer, it first meets the interior metallic layer of each conductive layer, then the conductive layer itself, and then the exterior metallic layer. On the other hand, when the light travels from the optical cladding layer to the optical core, it first meets the exterior metallic layer of each conductive layer, then the conductive layer itself, and then the interior metallic layer. The photovoltaic layer typically includes electrical connections such as probes, conductive traces or wires which are electrically coupled to the metallic layers. The electrical connections of multiple photovoltaic structures can be connected in series and/or parallel to provide direct current electrical power, as would be readily understood by a worker skilled in the art.

The interior metallic layer and exterior metallic layers are made of materials with high optical permeability and/or with good electric conductivity. In some embodiments, ITO (Indium Tin Oxide) and TCO (transparent conductive oxide) can be good candidate materials to implement these metallic layers.

The metallic layers may cover the entire height of the photovoltaic structures, or from the bottom up to the level “h” where the additional layer having anti-reflective outer surface is placed.

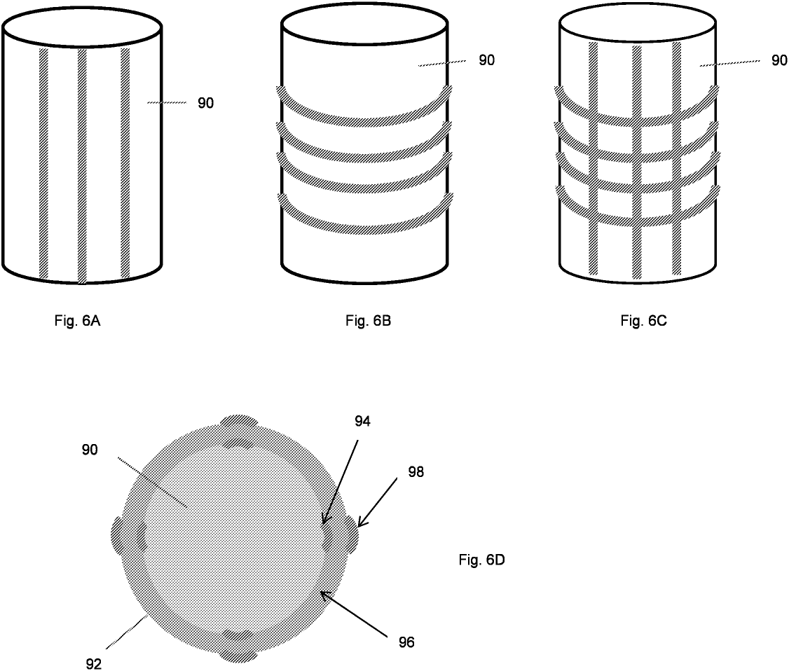

FIGS. 6A to 6C illustrate examples of different configurations of metallic layers on a optical core 90. FIG. 6D is the top view of FIG. 6A, showing optical core 90 surrounded by photovoltaic layer 92 having inner metallic layer 94, PN junction layer 96 and outer metallic layer 98.

The function of the optical cladding layer is to make the photovoltaic structures a good chamber for containing the incident light inside the photovoltaic structures so as to increase or even maximize the area of photovoltaic ECS., which can be achieved by selecting materials having appropriate refractive index and/or other material properties for the cladding layer as compared to the material(s) for the layers interior to the cladding layer. For example, the refractive indices of the cladding layer should be significantly different from that of the other layers interior to the cladding layer, so that the cladding layer will reflect light back inward. In various embodiments, the index of refraction of the cladding layer is much smaller than the refraction indices of all the other layers and that of the optical core.

Relative refractive index of the cladding layer can be selected/determined by using following equation known in the relevant art for determining reflectance at a surface;

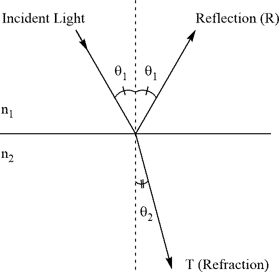

wherein n2 is the “optical cladding layer”, and n1 is the photovoltaic layer, or the core & the photovoltaic layer together. When n2 is smaller than n1, reflectance will be approach 1 (the maximum value), such that in the three dimensional photovoltaic structure substantial amount of the internal light will be reflected inwards.

In some embodiments, the cladding layer can be made of a material having refractive index of 0.1-1.5 with the above PV material layer (e.g. disposed substantially adjacent and interior to the cladding layer) having refractive index of 1.5-4.0 over the solar spectrum range 0.3-3 um.

In such embodiments, the cladding layer would act as a mirror, with key properties of (a) being a good reflectors and (b) having no transmission through the cladding layer. At the same time, the cladding layer may have a refractive index which is significantly different from materials (or air) external to the cladding layer. This will at least somewhat inhibit light from entering through the cladding layer by causing a reflection. Thus, the cladding layer will cause a major proportion of light incident thereon to be reflected back into the interior of the photovoltaic structure, while absorbing little to none of such light and allowing little to none of such light to leak out into the external environment.

In various embodiments, some light can enter through the cladding layer, typical on the order of 1-6% over the range of angles (1-179 deg) and wavelength (0.3-3 um). Such a transmission of light can be reduced by using a material with a high optical extinction coefficient combined with a thick material (which is typically needed electrically for the conductor component). Any metal will have an optical extinction coefficient greater than 2.5 over the solar spectrum, thus satisfying such criteria. The light is adsorbed in the surface of the layer as a loss. Such metals would have high absorption of light having wavelengths over the 0.3-3 um range.

In some embodiments, the inner surface of the cladding layer can be conductive as depicted in FIG. 5B. Such a layer serves functions; (1) a reflective element in the light capture cavity, and (2) a conductive layer in the active Photovoltaic cell. A conductive cladding can have an overall conductivity greater than 10^4 (1/ohm*m). This can be achieved by selecting materials that are good conductors and that can form effective ohmic contacts at the interface with the PV layer. Non limiting examples of conductive material include metals, such silver, chrome, aluminum, gold, iron, zinc, tantalum, molybdenum, etc., alloys, such as steel), and layered stacks of metals and or alloys.

Thickness the cladding layer can be from about 50 nm to about 5 mm. In various embodiments, in a cladding layer comprising multiple metal layers, the minimum thickness of each layer would be at least 3 nm.

FIG. 3 shows an example of optical propagation inside the non-conical shaped photovoltaic structure (such as a microprism, cylinder, cube, etc.)-the life of photons when a beam of incident light enters the photovoltaic structure. Photon w takes part in a photovoltaic event and successfully contributes to activation of an electron. Photon x penetrates the photovoltaic layer, gets bounced (reflected) back at the optical cladding layer, re-enters the photovoltaic layer and the optical core, and lands at the photovoltaic layer at the bottom of the photovoltaic structure where it contributes to a photovoltaic event. Photon y hits the optical cladding layer three times: once on the left wall, once at the bottom, and once on the right wall, and finally lands at the photovoltaic layer on the right wall of the microprism. Photon z lands at the photovoltaic layer on the left wall of the microprism after it hits the optical cladding layer three times and then gets bounced back at the top by the antireflection layer.

The similar principle applies to cone shaped photovoltaic structures. In case of conical photovoltaic structures the bottom end is defined by the apex or vertex of the cones. In such embodiments, the light-sealing chamber is formed by the walls of the cones and the additional layer at the top. However, in this case the bottom portion of the structure is reduced to a point, or nearly a point, and the sidewalls of the structure are non-parallel, thereby changing the paths of incident and reflected light.

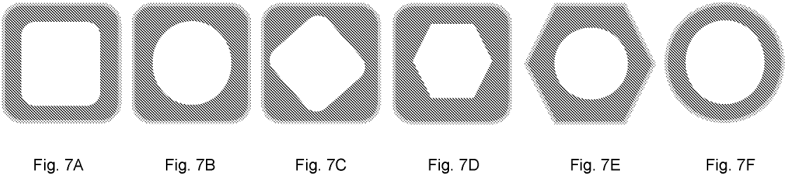

The cross sectional shapes of the optical core, the photovoltaic layer, the optical cladding layer and the stuffing layer can be same or different. In one embodiment, the cross sectional shape of the optical core, the photovoltaic layer, and the optical cladding layer is same (i.e. FIGS. 7A and 7F). In some embodiments, the cross-sectional shape of the photovoltaic layer and the optical cladding layer is different than the optical core (FIGS. 7B, 7C, 7D and 7E).

In another aspect of the present invention, there is provided a three dimensional photovoltaic power generation apparatus comprising a plurality of photovoltaic structures of the present invention as described above. The power generation apparatus comprises a base structure having an upper surface and a lower surface, wherein the lower surface is in direct or indirect association with the bottom end of each of the photovoltaic structures. In one embodiment, the photovoltaic power generation apparatus is a solar cell.

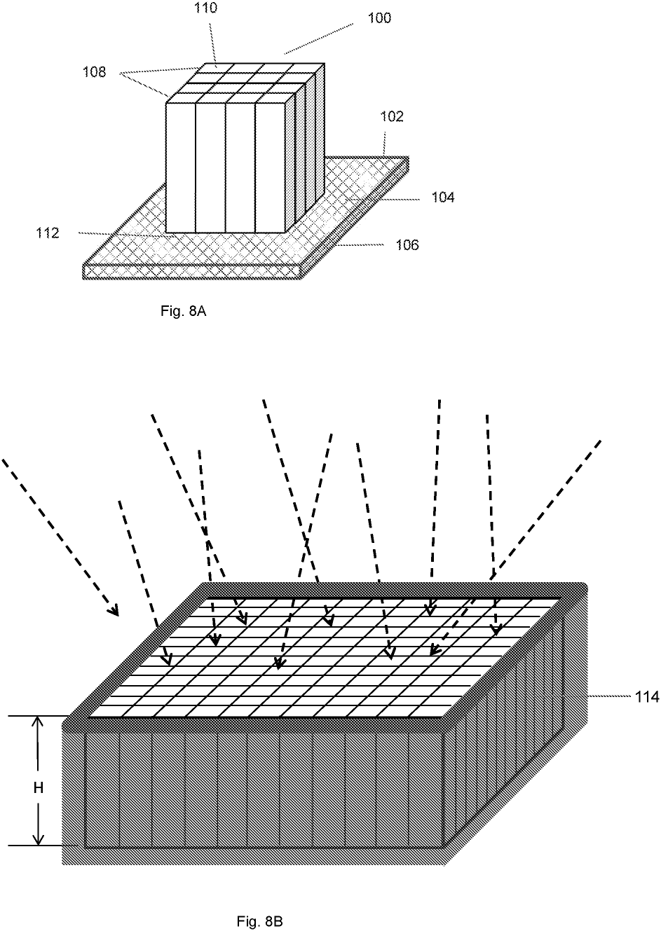

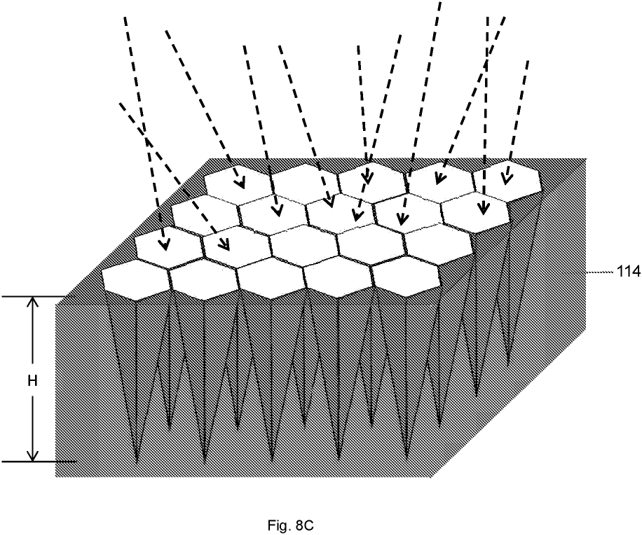

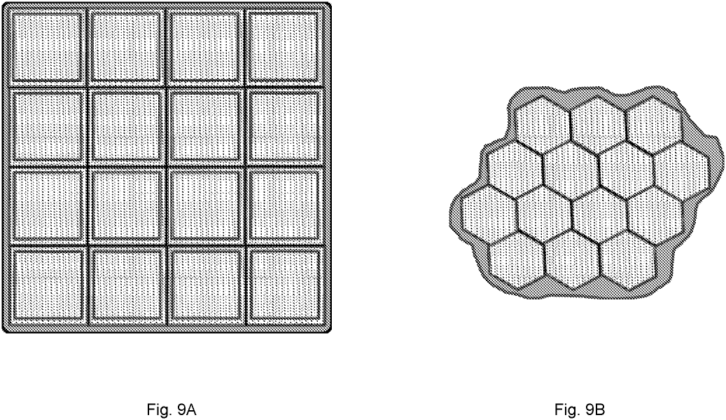

FIG. 8A illustrates an exemplary three dimensional photovoltaic power generation apparatus 100 comprising a base structure 102 having an upper surface 104 and a lower surface 106, and a plurality of photovoltaic structures 108 each having a top end 110, a bottom end 112. The bottom end 112 of each of the photovoltaic structures is in direct or indirect association with the upper surface 104 of the base structure.

In some embodiments, the base structure comprises side wall(s) 114 to encase the plurality of the photovoltaic structures (FIGS. 8B and 8C).

In some embodiments the side walls wrap all photovoltaic structures together like a solid ‘brick’.

In some embodiments, the photovoltaic structures can be packed together with gluing materials, and there may or may not be a case that contains all of the photovoltaic structures in a cell.

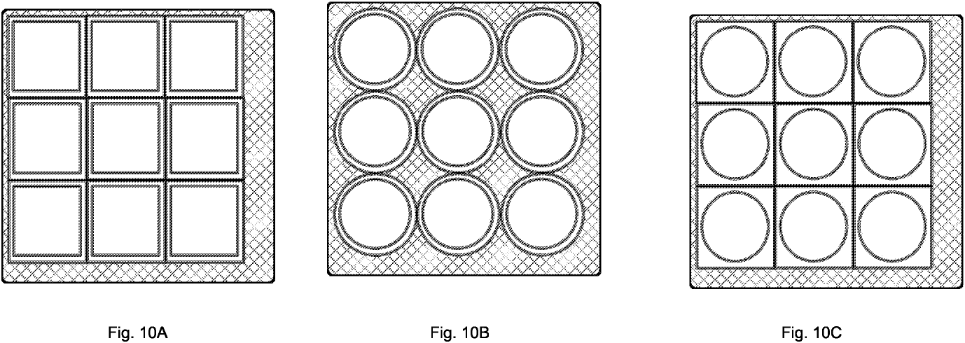

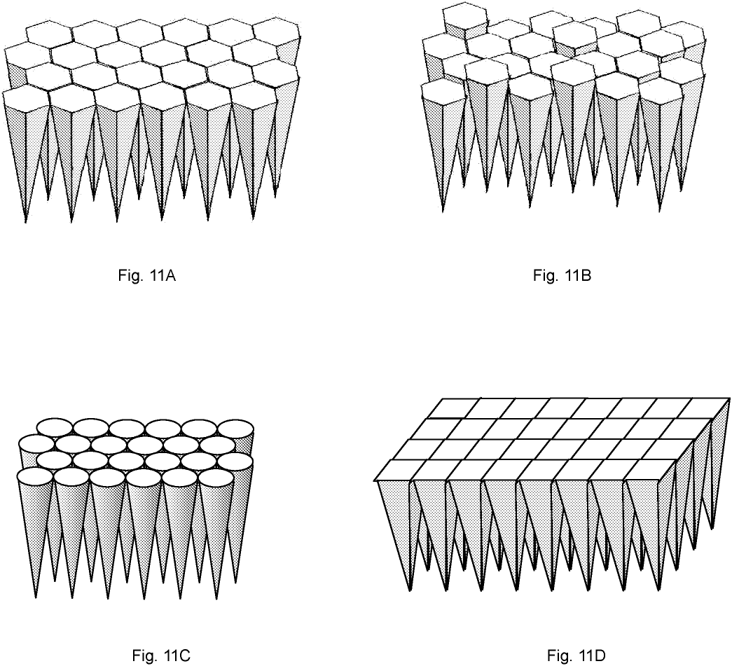

The three dimensional photovoltaic power generation apparatus/solar cell viewed from top can have a variety of geometrical shapes such a rectangular, square, triangle, hexagonal, etc. (for example as shown in FIGS. 9A, 9B, 10A, 10B and 10C, or any other shape).

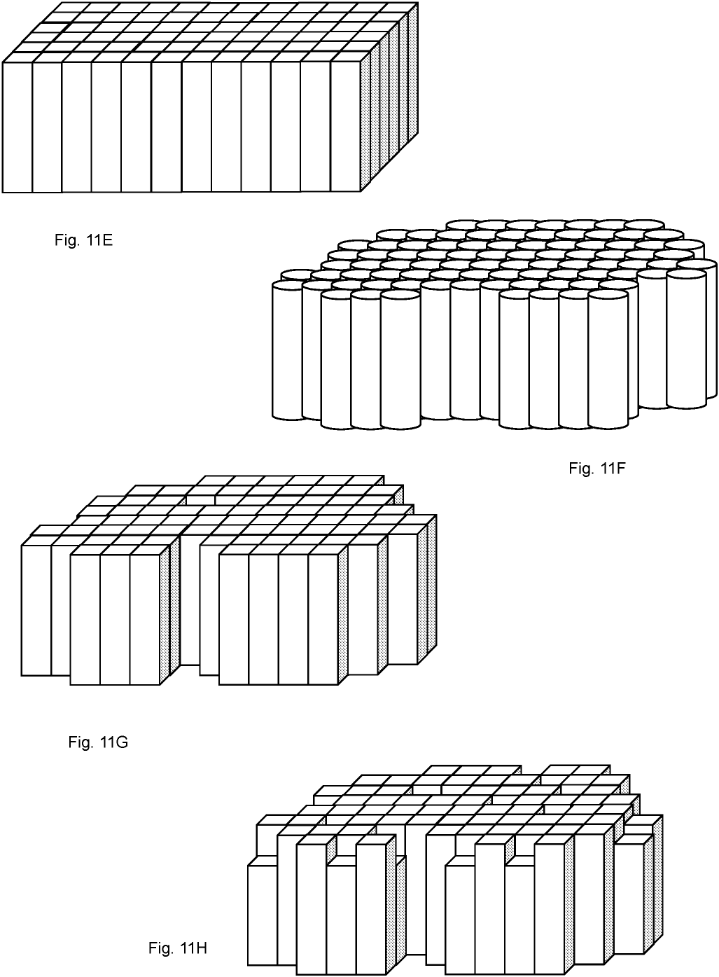

The heights of all photovoltaic structures in a photovoltaic power generation apparatus/solar cell can be the same as shown in FIGS. 11A, 11C, 11D, 11G, and 11E or can be different as shown in FIGS. 11B, 11F, and 11H.

Although in various illustrated embodiments the bottom face of the non-conical photovoltaic structures is flat, it is possible that the bottom face may be curved. For example, the structure may be hemispherical in shape.

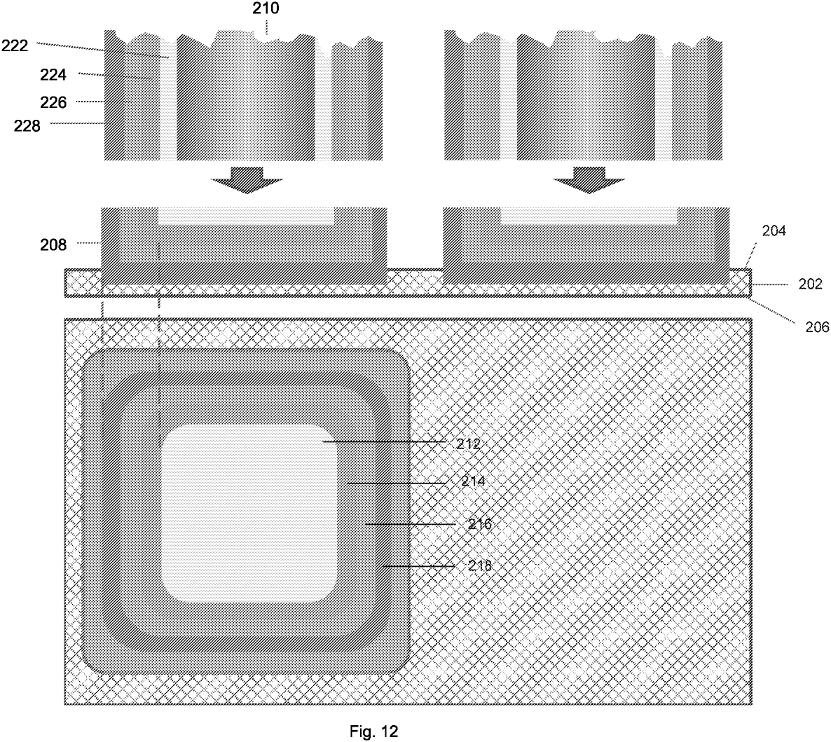

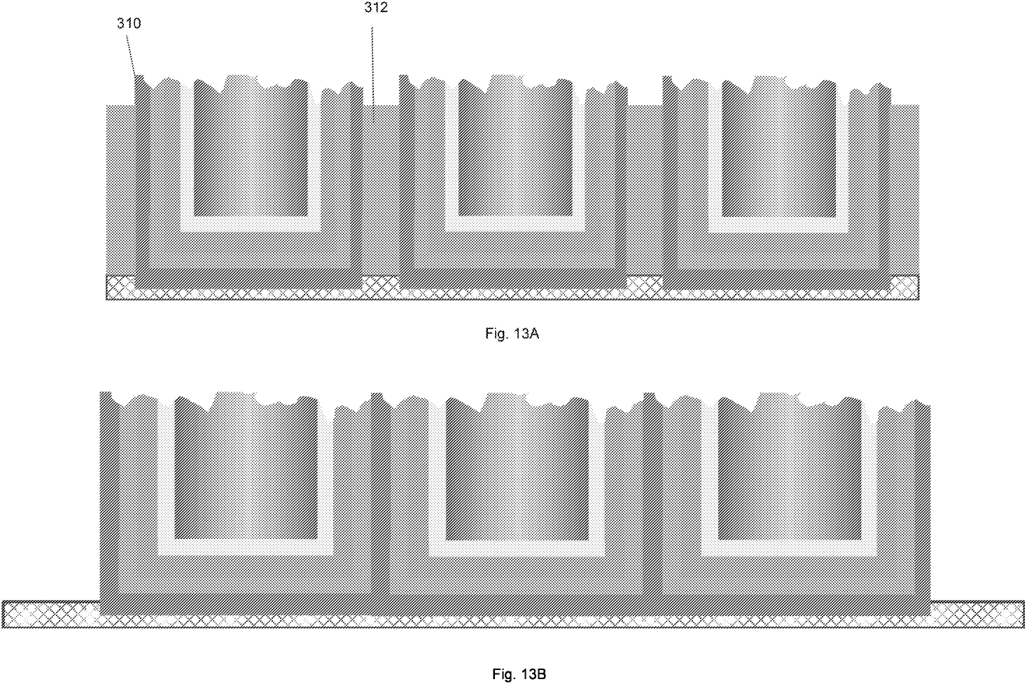

In some embodiments, the upper surface of the base structure has a plurality of receiving structures shaped to accommodate the shape of the bottom of a corresponding photovoltaic structure. For example, in the case of non-conical photovoltaic structures (such as microprisms), the base structure seals the bottoms of all photovoltaic structures of the same cell with all functions that are provided by the walls of the photovoltaic structures (FIG. 12).

In some embodiments, the photovoltaic layer and the cladding layer surround the bottom end of the optical core. In some embodiments of non-conical photovoltaic structures (such as microprisms, cube, etc.), the portion of the photovoltaic layer and the cladding layer surrounding the bottom end of the optical core is integral to the base structure. For example, referring to a microprism shaped photovoltaic structure, the base structure contains a plurality of units each of which connects to one and exactly one microprism that stands on it. The base structure is prepared with all the units having exactly the same layered structure as the walls of the microprisms, that is, a photovoltaic layer which may contain a plurality of PN junction layers and their associated metallic layers, and an optical cladding layer as the outermost layer. The one-to-one correspondence of these layers of the base structure with the layers of the walls makes a seamless encapsulation around the optic core of the microprisms, leaving only the top open with an antireflection layer slightly underneath the top (for example as shown in FIGS. 2A and 2B). The photovoltaic layer and the optical cladding layer portions of both the base structure and the photovoltaic structure are aligned so as to provide contiguous layered structures.

FIG. 12 illustrates an exemplary receiving structure 208 of base structure 202 having upper surface 204 and lower surface 206, and its integration with a corresponding photovoltaic structure 210. In this example, the receiving structure has an internal metallic layer 212, PN junction layer 214, external metallic layer 216, and optical cladding layer 218, each of which correspond to their respective layers of the corresponding photovoltaic structure 210 (i.e. an internal metallic layer 222, PN junction layer 224, external metallic layer 226, and optical cladding layer 228).

In the embodiments comprising cone shaped photovoltaic structures there is no such step of bottom processing.

As discussed above, the photovoltaic structures of the present invention optionally comprise a stuffing layer surrounding the optical cladding layer. The plurality of photovoltaic structures can be assembled with or without an additional stuffing layer between the assembled photovoltaic structures.

In one embodiment, non-conical photovoltaic structures are assembled with or without an additional stuffing layer. In one embodiment, conical photovoltaic structures are assembled with an additional stuffing layer.

The function of the stuffing layer is to provide the power generation apparatus/solar cell with mechanical features (such as load bearing) or operational features (such as sensor) as desired or required.

FIG. 13A illustrates an example of the power generation apparatus/solar cell with additional stuffing layer 312 between adjacent non-conical photovoltaic structures 310. FIG. 13B illustrates an example of power generation apparatus/solar cell without additional stuffing between adjacent non-conical photovoltaic structures.

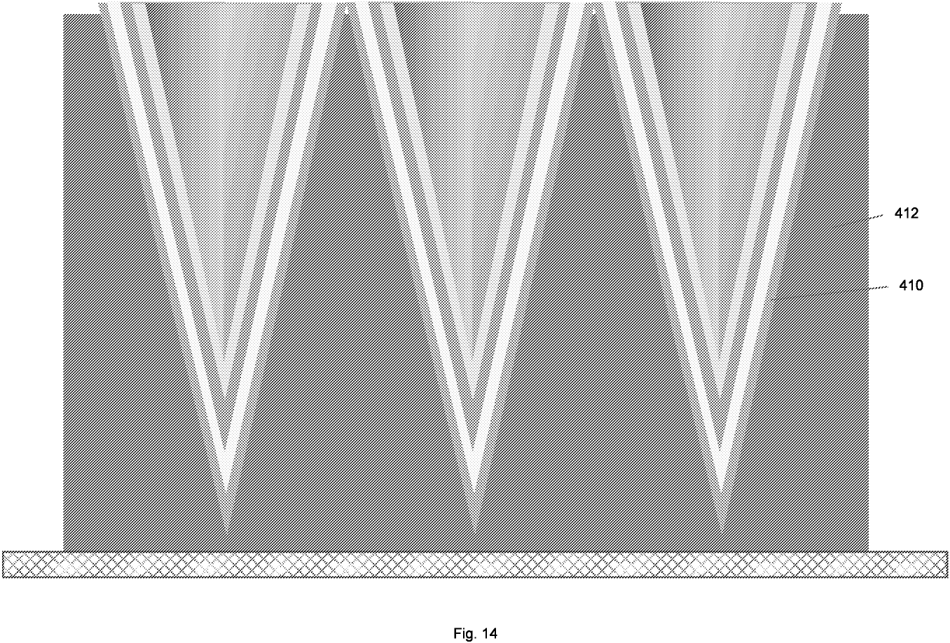

FIG. 14 illustrates an exemplary power generation apparatus/solar cell with an additional stuffing layer 412 between cone shaped photovoltaic structures 410.

In some embodiments, for the case of cone shaped photovoltaic structures, a stuffing layer is provided in order to make a rectangular 3-D solar cell.

The power generation apparatus of the present invention also comprises electrical wiring and connections to convert the energy of light into electricity by the photovoltaic effect. The electrical wiring and connections are as known in the art.

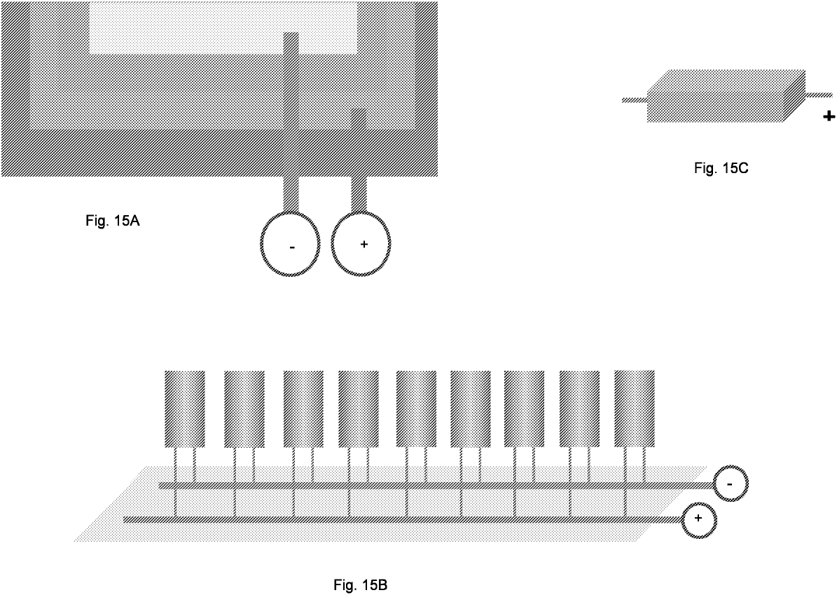

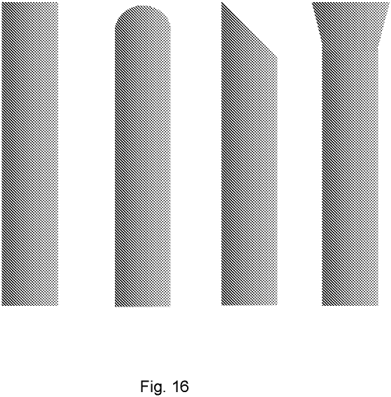

FIGS. 15A to 15C illustrate schematic depiction of electrical wirings inside a power generation apparatus/solar cell of the present invention. FIG. 15A shows a pair of DC connection wires coming out of each photovoltaic structure. The photovoltaic structures of the same power generation apparatus/solar cell are electrically connected in parallel (FIG. 15B) to collect tiny electric currents resulting from the photovoltaic effects of all photovoltaic structures. As a result of such integration, a finished solar cell is seen from outside to have one positive electrode and one negative electrode (FIG. 15C).

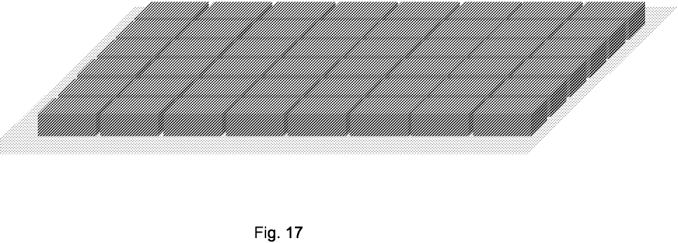

The top ends of all photovoltaic structures are directly exposed to the sunlight, and therefore the power generation apparatus/solar cells have one side that receives the solar radiation, for example as shown in FIG. 17. In certain embodiments for certain purposes, the tops maybe processed into different geometric shapes, and may be coated with a thin anti-dust film.

Finished power generation apparatus of the present invention can be used in a wide range of applications, for example to construct pavements on virtually any surfaces. FIG. 17 illustrates an array of power generation apparatus/solar cell disposed on a surface.

In another aspect of the present invention there is provided a systematic method to significantly increase the ECS for a given solar cell with given surface area.

It is obvious that the foregoing embodiments of the invention are examples and can be varied in many ways. Such present or future variations are not to be regarded as a departure from the spirit and scope of the invention, and all such modifications as would be obvious to one skilled in the art are intended to be included within the scope of the following claims.

1. A three dimensional photovoltaic structure, comprising:
a light transmitting solid optical core having a longitudinal axis, said core having a top end, a bottom end and one or more side walls,
the top end having an exposed outer surface to receive light;
a photovoltaic layer adjacent the optical core and surrounding the bottom end of the optical core and the one or more of the side walls of said optical core; and
an optical cladding layer adjacent the optical core and surrounding said photovoltaic layer;
wherein said photovoltaic layer surrounding the bottom end of the optical core and the one or more side walls of said optical core, and the optical cladding layer surrounding said photovoltaic layer, together define a substantially closed light sealing optical chamber,
wherein the three dimensional structure receives light substantially through the exposed outer surface of the top end of the optical core, the photovoltaic layer receives light from the core, and the optical cladding layer receives light through the photovoltaic layer, and reflect it back towards the photovoltaic layer.

2. The photovoltaic structure of claim 1, wherein said photovoltaic structure is shaped as a geometric prism.

3. The photovoltaic structure of claim 1, wherein said photovoltaic structure has a conical shape, wherein the bottom end of the photovoltaic structure is defined by converging side walls to form an apex or vertex thereof, and the light sealing optical chamber is defined by the side walls.

4. The photovoltaic structure of claim 1, wherein the optical cladding layer has a refractive index less than a refractive index of the optical core and the photovoltaic layer.

5. The photovoltaic structure of any claim 4, wherein the optical core has a refractive index which is less than or approximately equal to a refractive index of the photovoltaic layer.

6. The photovoltaic structure of claim 1, wherein said optical core is made of non-conductive, non-opaque and/or an optically permeable material.

7. The photovoltaic structure of claim 1, further comprising an additional layer at or near the top end, said additional layer having an anti-reflective light transmitting outer surface and a reflective inner surface.

8. The photovoltaic structure of claim 1, wherein said photovoltaic layer comprises a multilayered structure comprising: an interior metallic layer in contact with the optical core, one or more semiconductor layers comprising one or more PN junctions and surrounding the interior layer, and an exterior metallic layer surrounding the semiconductor layer, wherein the interior metallic layer and the exterior metallic layer are electrically coupled to conductors for providing an electric voltage.

9. The photovoltaic structure of claim 8, wherein said photovoltaic layer comprises multiple tandem semiconductor layers with spectrum selectivity in axial, radial and/or circular direction.

10. The photovoltaic structure of claim 8, wherein the semiconductor layer has a polarity to impart movement of electrons toward or away from the optical core during a photovoltaic event.

11. The photovoltaic structure of claim 1, wherein the photovoltaic layer has a first portion surrounding the bottom end of the optical core and a second portion surrounding the one or more side walls of said optical core, wherein the first portion and the second portion are formed from one or more photovoltaic materials tuned to a same waveband.

12. A three dimensional photovoltaic power generation apparatus, comprising:
a base structure having an upper surface and a lower surface; and
a plurality of three dimensional photovoltaic structures as defined in claim 1,
wherein said bottom end portion of each of said plurality of photovoltaic structures is in direct or indirect contact with said upper surface of said base structure.

13. The apparatus according to claim 12, wherein said structure further comprises one or more side walls to encase said plurality of said photovoltaic structures.

14. The apparatus according to claim 12, wherein the apparatus further comprises a stuffing layer between adjacent photovoltaic structures and/or a stuffing layer between the bottom end portions of the photovoltaic structures and the upper surface of the base structure to provide said indirect association.

15. The apparatus according to claim 12, wherein said photovoltaic structures have a conical shape, wherein the bottom end of the photovoltaic structure is defined by converging side walls to form an apex or vertex thereof, and the light sealing optical chamber is defined by the side walls.

16. The apparatus according to claim 15, wherein the apex or vertex of each of the photovoltaic structures are in contact with the upper surface of the base structure to provide said direct contact.

17. The apparatus according to claim 12, wherein said photovoltaic structures are shaped as geometric prisms.

18. The apparatus according to any claim 17, wherein the upper surface of said base structure has a plurality of receiving structures shaped to accommodate the bottom end portions of corresponding photovoltaic structures.

19. The apparatus according to claim 18, the photovoltaic layer and the cladding layer surrounding the bottom end of the optical core is integral to the base structure, wherein the upper surface of the base structure comprises a layered structure comprising a photovoltaic layer and the cladding layer, wherein each layer abuts with the corresponding photovoltaic layer and the cladding layer of the photovoltaic structures.
